(19) United States
(12) Patent Application Publication
(10) Pub. No.: US 2025/0248260 A1
(43) Pub. Date: Jul. 31, 2025

(54) DISPLAY DEVICE AND MANUFACTURING METHOD THEREOF

(71) Applicant: Samsung Display Co., Ltd., Yongin-Si (KR)

(72) Inventors: EOK SU KIM, Yongin-si (KR); HYELIM CHOI, Yongin-si (KR)

(21) Appl. No.: 18/951,648

(22) Filed: Nov. 19, 2024

(30) Foreign Application Priority Data
Jan. 31, 2024 (KR) 10-2024-0014723

(51) Int. Cl. H10K 59/131; H10K 59/12; H10K 59/123

(52) U.S. Cl. CPC H10K 59/1315; H10K 59/1201; H10K 59/123

(57) ABSTRACT

A display device is disclosed that includes a base substrate, a transistor disposed on the base substrate and including a semiconductor pattern including a source region, an active region and a drain region, and a gate electrode, a gate insulating pattern layer disposed on the semiconductor pattern, an oxygen supply pattern disposed between the gate insulating pattern layer and the gate electrode, overlapping the active region, and configured to supply oxygen to the active region, and a connection electrode disposed on the gate insulating pattern layer and electrically connected to the semiconductor pattern, wherein a first hole disposed to be adjacent to either the source region or the drain region may be defined in the semiconductor pattern, and the connection electrode may be directly in contact with the semiconductor pattern.

### CROSS-REFERENCE TO RELATED APPLICATIONS

This U.S. non-provisional patent application claims priority under 35 U.S.C. § 119 of Korean Patent Application No. 10-2024-0014723, filed on Jan. 31, 2024, the entire contents of which are hereby incorporated by reference.

### BACKGROUND

The present disclosure herein relates to a display device and a manufacturing method thereof.

Multimedia devices such as televisions, mobile phones, tablet PCs, computers, navigation devices, and game consoles may include a display panel for displaying an image. The display panel may include a plurality of pixels for displaying an image, and each of the pixels may include a light-emitting element which generates light and a driving element which is connected to the light-emitting element.

The light-emitting element and the driving element of the display panel may be formed through stacking a thin film and patterning the thin film using a mask. Since a manufacturing process for a display panel using a mask is expensive, it is desirable to simplify the manufacturing process for the display panel to reduce the number of masks used for manufacturing the display device. Also, it is desirable to manufacture a display panel having reliability when a manufacturing process is simplified.

### SUMMARY

The present disclosure may provide a display device having improved display quality and ensured reliability by reducing contact resistance between elements.

An embodiment of the inventive concept provides a display device including a base substrate, a transistor disposed on the base substrate and including a semiconductor pattern including a source region, an active region and a drain region, and a gate electrode, a gate insulating pattern layer disposed on the semiconductor pattern, an oxygen supply pattern disposed between the gate insulating pattern layer and the gate electrode, overlapping the active region, and configured to supply oxygen to the active region, and a connection electrode disposed on the gate insulating pattern layer and electrically connected to the semiconductor pattern, wherein a first hole disposed to be adjacent to either the source region or the drain region may be defined in the semiconductor pattern, and the connection electrode may be directly in contact with the semiconductor pattern.

In an embodiment, the gate insulating pattern layer may be disposed on the active region and include a gate insulating pattern having a shape corresponding to the active region, and a shape of the oxygen supply pattern may correspond to the gate insulating pattern.

In an embodiment, the oxygen supply pattern may overlap the active region.

In an embodiment, the connection electrode may be provided in plurality, and the plurality of the connection electrodes may include a first connection electrode directly in contact with the drain region and a second connection electrode directly in contact with the source region.

In an embodiment, the drain region may include a first drain portion having first conductivity and a second drain portion extending from the first drain portion and having second conductivity which is lower than the first conductivity, and the source region may include a first source portion having third conductivity and a second source portion extending from the first source portion and having fourth conductivity which is lower than the third conductivity.

In an embodiment, the first connection electrode may be directly in contact with the first drain portion, and the second connection electrode may be directly in contact with the first source portion.

In an embodiment, in a plan view, the first hole may be surrounded by the first source portion, or may be surrounded by the first drain portion.

In an embodiment, the display device may further include a first conductive pattern and a second conductive pattern disposed between the base substrate and the transistor and spaced apart from each other in a plan view, wherein the first conductive pattern may be electrically connected to the first drain portion through the first connection electrode, and the second conductive pattern may be electrically connected to the first source portion through the second connection electrode.

In an embodiment, the display device may further include an additional insulating layer disposed on a lower surface of the connection electrode and not overlapping with the active region, wherein the additional insulating layer and the oxygen supply pattern may be disposed on the same layer and include the same material.

In an embodiment, the additional insulating layer may include a material having greater electrical resistance than the connection electrode.

In an embodiment, an inner side surface of the semiconductor pattern defining the first hole and one side surface of the connection electrode adjacent to the inner side surface may be spaced apart from each other.

In an embodiment, the display device may further include a light-emitting element disposed on the connection electrode and including a first electrode connected to the connection electrode, an emission layer, and a second electrode, wherein the connection electrode may electrically connect the first electrode and the transistor.

In an embodiment, the connection electrode and the gate electrode may be disposed on the same layer and may include the same material.

In an embodiment of the inventive concept, a display device includes a base substrate, a transistor disposed on the base substrate and including a semiconductor pattern including a source region, an active region and a drain region, and a gate electrode, a gate insulating pattern layer disposed on the semiconductor pattern, an oxygen supply pattern layer disposed on the gate insulating pattern layer, and a connection electrode disposed on the gate insulating pattern layer and electrically connected to the semiconductor pattern, wherein a first hole disposed to be adjacent to either the source region or the drain region may be defined in the semiconductor pattern, and the oxygen supply pattern layer may include a first oxygen supply pattern disposed between the gate insulating pattern layer and the gate electrode and a second oxygen supply pattern directly disposed on a lower surface of the connection electrode and not overlapping the active region.

In an embodiment, the connection electrode may be directly in contact with the source region or the drain region.

In an embodiment of the inventive concept, a method of manufacturing a display device includes preparing a preliminary display device including a base substrate, a preliminary semiconductor pattern including a source region, an active region, and a drain region disposed on the base substrate, and a gate insulating pattern layer disposed on the preliminary semiconductor pattern, forming an oxygen supply pattern layer on the gate insulating pattern layer, forming a first opening exposing a first portion of the preliminary semiconductor pattern in the gate insulating pattern layer and the oxygen supply pattern layer, forming a conductive layer on the oxygen supply pattern layer, forming a gate electrode and a connection electrode from the conductive layer by forming a second opening exposing a portion of the first portion of the preliminary semiconductor pattern in the conductive layer, and forming a semiconductor pattern from the preliminary semiconductor pattern by forming a first hole disposed to be adjacent to either the source region or the drain region in the preliminary semiconductor pattern.

In an embodiment, the connection electrode may be directly in contact with the source region or the drain region.

In an embodiment, the method may further include, after forming the first opening, doping the first portion of the preliminary semiconductor pattern exposed by the first opening.

In an embodiment, the forming of the gate electrode and the connection electrode may include forming a photoresist layer having a photo opening defined therein on the conductive layer, and etching the conductive layer.

In an embodiment, the drain region may include a first drain portion having first conductivity and a second drain portion extending from the first drain portion and having second conductivity which is lower than the first conductivity, the source region may include a first source portion having third conductivity and a second source portion extending from the first source portion and having fourth conductivity which is lower than the third conductivity, the connection electrode may be provided in plurality, and the plurality of connection electrodes may include a first connection electrode directly in contact with the first drain portion and a second connection electrode directly in contact with the first source portion.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display device according to an embodiment of the inventive concept;

FIG. 2A is an exploded perspective view of a display device according to an embodiment of the inventive concept;

FIG. 2B is a cross-sectional view of a display module according to an embodiment of the inventive concept;

FIG. 3 is a plan view of a display panel according to an embodiment of the inventive concept;

FIG. 4 is a cross-sectional view taken along line I-I′ of FIG. 3 according to an embodiment of the inventive concept;

FIG. 5 is a plan view corresponding to a circuit layer of FIG. 4 according to an embodiment of the inventive concept;

FIG. 6 is an enlarged plan view of a region AA′ of FIG. 5 according to an embodiment of the inventive concept;

FIG. 7 is a cross-sectional view taken along line II-II′ of FIG. 6 according to an embodiment of the inventive concept; and

FIGS. 8A to 8H are cross-sectional views partially showing a manufacturing method of a display device according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween.

Like reference numerals or symbols refer to like elements. Also, in the drawings, the thicknesses, ratios, and dimensions of elements are exaggerated for effective description of technical contents. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well unless the context clearly indicates otherwise.

Also, terms such as “below”, “on lower side”, “above”, and “on upper side” are used to describe the relationships of the elements illustrated in the drawings. These terms have relative concepts and are described on the basis of the directions indicated in the drawings.

It will be understood that the terms such as “comprise”, “include”, and “have” (and their variations such as “comprising”), when used herein, are intended to specify the presence of stated features, integers, steps, operations, elements, components, or combinations thereof, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the inventive concept belongs. Also, terms such as those defined in commonly used dictionaries should be interpreted as having a meaning that is consistent with their meaning in the context of the relevant art and should not be interpreted in an idealized or overly formal sense unless expressly so defined herein.

Hereinafter, embodiments of the inventive concept will be described with reference to the accompanying drawings.

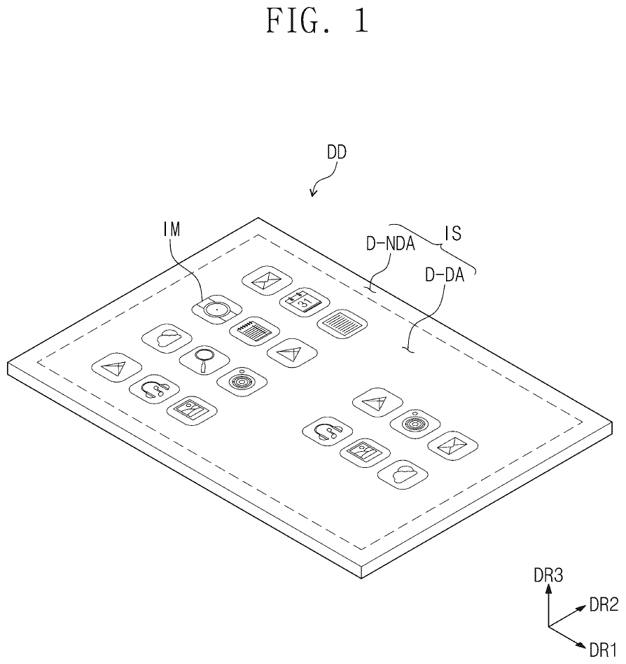

FIG. 1 is a perspective view of a display device according to an embodiment of the inventive concept.

Referring to FIG. 1, a display device DD may be activated in response to an electrical signal and display an image. The display device DD may include various embodiments which provide an image IM to a user, and for example, the display device DD may be a large-sized device such as a television and an outdoor billboard, as well as a small-or medium-sized device such as a monitor, a mobile phone, a tablet PC, a navigation device, and a game console. Meanwhile, embodiments of the display device DD are examples, and the display device DD is not limited to any one embodiment unless the display device DD departs from the scope of the inventive concept.

The display device DD may have a rectangular shape having long sides extending in a first direction DR1 and short sides extending in a second direction DR2 in a plan view. However, an embodiment of the inventive concept is not limited thereto, and the display device DD may have various shapes such as a circular shape or a polygonal shape.

The display device DD may display the image IM in a third direction DR3 through a display surface IS parallel to a plane defined by the first direction DR1 and the second direction DR2. The third direction DR3 may be substantially parallel to a normal direction of the display surface IS. The display surface IS through which the image IM is displayed may correspond to a front surface of the display device DD. The image IM may include a static image as well as a dynamic image. FIG. 1 illustrates icon images as an example of the image IM.

In this embodiment, a front surface (or an upper surface) and a rear surface (or a lower surface) of each of members constituting the display device DD may be defined on the basis of the third direction DR3. A front surface and a rear surface may be opposed to each other in the third direction DR3, and a normal line of each of a front surface and a rear surface may be parallel to the third direction DR3. A distance between a front surface and a rear surface defined along the third direction DR3 may correspond to a thickness of a member.

As used herein, the wording “in a plan view” may be defined as a state of being viewed in the third direction DR3. As used herein, the wording “in a cross-sectional view” may be defined as a state of being viewed in the first direction DR1 or the second direction DR2. However, directions indicated by the first to third directions DR1, DR2, and DR3 may have relative concepts and may thus be changed into other directions.

FIG. 1 exemplarily illustrates the display device DD having a flat display surface IS. However, a form of the display surface IS of the display device DD is not limited thereto, and the display surface IS may be a curved display surface or a three-dimensional display surface.

The display device DD may be flexible. The term “flexible” may imply a bendable property, and the display device DD may be a device including any one from among a structure which is completely foldable to a structure which is bendable to a level of several nanometers. For example, the flexible display device DD may include a curved device or a foldable device. However, an embodiment of the inventive concept is not limited thereto, and the display device DD may be rigid.

The display surface IS of the display device DD may include a display portion D-DA and a non-display portion D-NDA. The display portion D-DA may be a portion in which the image IM is displayed in the front surface of the display device DD, and a user may view the image IM through the display portion D-DA. In this embodiment, the display portion D-DA having a quadrangular shape in a plan view is exemplarily illustrated, but the display portion D-DA may have various shapes according to a design of the display device DD.

The non-display portion D-NDA may be a portion in which the image IM is not displayed in the front surface of the display device DD. The non-display portion D-NDA may be a portion which has a predetermined color and blocks light. The non-display portion D-NDA may be adjacent to the display portion D-DA. For example, the non-display portion D-NDA may be disposed outside the display portion D-DA and surround the display portion D-DA. However, this is exemplarily illustrated, and the non-display portion D-NDA may be adjacent to only one side of the display portion D-DA or disposed on a side surface, not the front surface, of the display device DD. An embodiment of the inventive concept is not limited thereto, and the non-display portion D-NDA may also be omitted.

The display device DD of an embodiment may sense an external input applied from the outside. The external input may have various forms such as temperature, light, and pressure provided from the outside. The external input may include not only an input that contacts the display device DD (e.g., a contact by a user's hand or a pen), but also an input applied close to the display device DD (e.g., hovering).

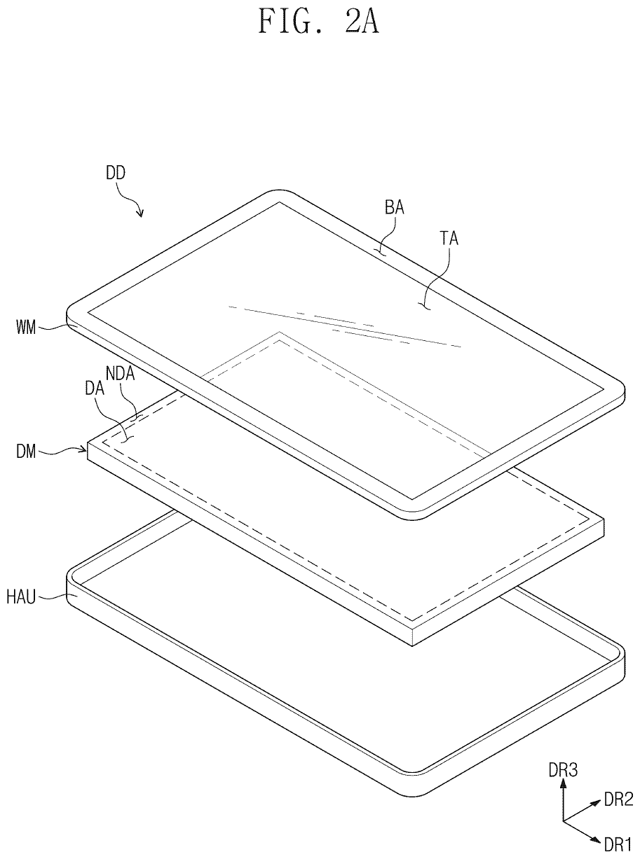

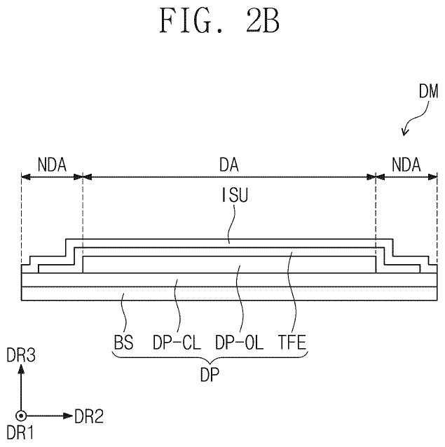

FIG. 2A is an exploded perspective view of a display device according to an embodiment of the inventive concept. FIG. 2B is a cross-sectional view of a display module according to an embodiment of the inventive concept.

Referring to FIGS. 2A and 2B, a display device DD may include a window WM, a display module DM, and a housing HAU. The display module DM may include a display panel DP and a light control member.

The window WM and the housing HAU may be coupled to each other to form an exterior of the display device DD and to provide an inner space capable of accommodating components of the display device DD such as the display module DM.

The window WM may be disposed on the display module DM. The window may protect the display module DM from an external impact. A front surface of the window WM may correspond to the display surface IS of the display device DD described above. The front surface of the window WM may include a transmission region TA and a bezel region BA.

The transmission region TA of the window WM may be an optically transparent region. The window WM may transmit an image provided by the display module DM through the transmission region TA, and a user may view the image. The transmission region TA may correspond to the display portion D-DA of the display device DD described above.

The window WM may include an optically transparent insulating material. For example, the window WM may include glass, sapphire, or plastic. The window WM may have a single-layered structure or a multi-layered structure. The window WM may further include a functional layer such as an anti-fingerprint layer, a phase control layer, or a hard coating layer disposed on an optically transparent substrate.

The bezel region BA of the window WM may be provided as a region in which a material having a predetermined color is deposited, applied, or printed on a transparent substrate. The bezel region BA of the window WM may prevent a component of the display module DM disposed to overlap the bezel region BA from being viewed from the outside. The bezel region BA may correspond to the non-display portion D-NDA of the display device DD described above.

The display module DM may be disposed between the window WM and the housing HAU. The display module DM may display an image in response to an electrical signal. The display module DM may include a display region DA and a non-display region NDA adjacent to the display region DA.

The display region DA may be a region which is activated in response to an electrical signal and in which an image is outputted. The display region DA of the display module DM may overlap the transmission region TA of the window WM. Meanwhile, as used herein, the wording “a region/portion and a region/portion overlap each other” is not limited to a case in which regions/portions have the same area size or the same shape. The image outputted from the display region DA may be viewed from the outside through the transmission region TA.

The non-display region NDA may be adjacent to the display region DA. For example, the non-display region NDA may surround the display region DA. However, an embodiment of the inventive concept is not limited thereto, and the non-display region NDA may be defined in various shapes. The non-display region NDA may be a region in which a driving line or a driving circuit for driving elements disposed in the display region DA, various types of signal lines for providing an electrical signal, and pads are disposed. The non-display region NDA of the display module DM may overlap the bezel region BA of the window WM, and components disposed in the non-display region NDA may be prevented from being viewed from the outside by the bezel region BA.

The display panel DP according to an embodiment may be an emissive display panel, and is not particularly limited thereto. For example, the display panel DP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, etc. Hereinafter, the display panel DP will be described as an organic light-emitting display panel.

The display panel DP may include a base substrate BS, a circuit layer DP-CL, a display element layer DP-OL, and an encapsulation layer TFE.

The base substrate BS may provide a base surface on which the circuit layer DP-CL is disposed. The base substrate BS may be a rigid substrate, but is not limited thereto and may be a flexible substrate.

The circuit layer DP-CL may be disposed on the base substrate BS. The circuit layer DP-CL may include driving elements such as a transistor, signal lines, and signal pads. The display element layer DP-OL may include light-emitting elements disposed to overlap the display region DA. The light-emitting elements of the display element layer DP-OL may be electrically connected to the driving elements of the circuit layer DP-CL and output light through the display region DA in response to a signal from the driving elements.

The encapsulation layer TFE may be disposed on the display element layer DP-OL and encapsulate the light-emitting elements. The encapsulation layer TFE may include a plurality of thin films. The thin films of the encapsulation layer TFE may be disposed so as to improve optical efficiency of the light-emitting elements or to protect the light-emitting elements.

A sensor layer ISU may be disposed on the display panel DP. The sensor layer ISU may sense an external input applied from the outside. The external input may be a user's input. A user's input may include external inputs in various forms such as a part of the user's body, light, heat, a pen, or pressure.

The sensor layer ISU may be disposed on the display panel DP through a continuous process. The sensor layer ISU may be directly disposed on the display panel DP. Being directly disposed may mean that an intervening element is not disposed between the sensor layer ISU and the display panel DP. That is, an additional adhesive member may not be disposed between the sensor layer ISU and the display panel DP.

Alternatively, the sensor layer ISU and the display panel DP may be bonded to each other through an adhesive member. The adhesive member may include typical adhesive agent or bonding agent.

The housing HAU may be disposed under the display module DM and accommodate the display module DM. The housing HAU may protect the display module DM by absorbing an impact applied to the display module DM from the outside and preventing foreign substances/moisture, etc. from being introduced into the display module DM. The housing HAU of an embodiment may be provided in a form in which a plurality of accommodation members are coupled to each other.

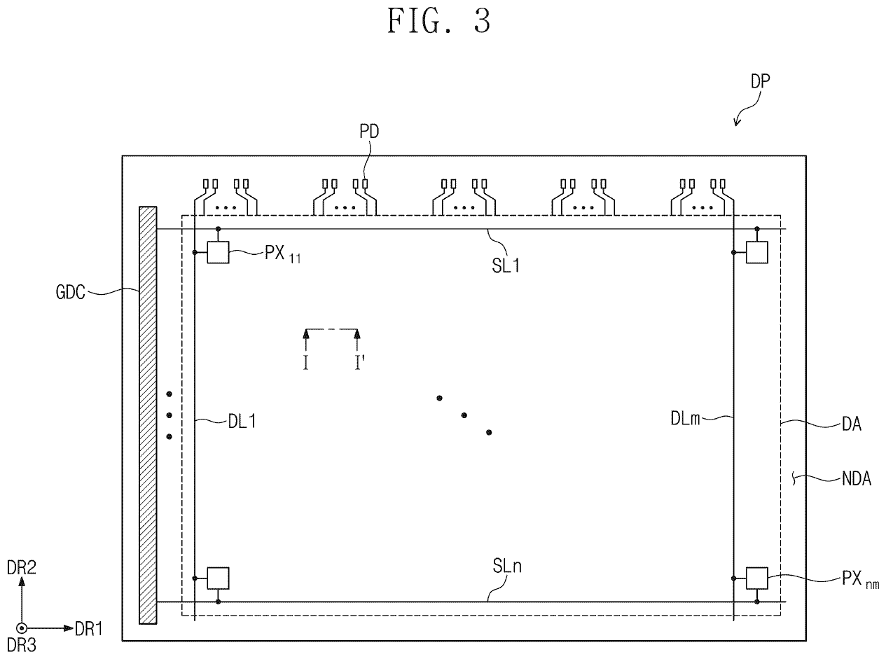

FIG. 3 is a plan view of a display panel according to an embodiment of the inventive concept.

Referring to FIG. 3, a display panel DP may include pixels PX₁₁ to PXₙₘ disposed in a display region DA and signal lines SL1 to SLn and DL1 to DLm electrically connected to the pixels PX₁₁ to PXₙₘ. The display panel DP may include pads PD and a driving circuit GDC disposed in a non-display region NDA.

Each of the pixels PX₁₁ to PXₙₘ may include a pixel driving circuit including a light-emitting element, a plurality of transistors (e.g., a switching transistor, a driving transistor, etc.) connected to the light-emitting element, and a capacitor. The pixels PX₁₁ to PXₙₘ may emit light in response to an electrical signal applied to the pixels PX₁₁ to PXₙₘ. FIG. 3 exemplarily illustrates the pixels PX₁₁ to PXₙₘ arranged in a matrix form, but an arrangement of the pixels PX₁₁ to PXₙₘ is not limited thereto.

The signal lines SL1 to SLn and DL1 to DLm may include scan lines SL1 to SLn and data lines DL1 to DLm. Each of the pixels PX₁₁ to PXₙₘ may be connected to a corresponding scan line among the scan lines SL1 to SLn and a corresponding data line among the data lines DL1 to DLm. More various types of signal lines may be included in the display panel DP according to the configuration of the pixel driving circuit of the pixels PX₁₁ to PXₙₘ.

The driving circuit GDC may include a gate driving circuit. The gate driving circuit may generate gate signals and sequentially output the gate signals to the scan lines SL1 to SLn. The gate driving circuit may further output another control signal to the pixel driving circuit of the pixels PX₁₁ to PXₙₘ.

The driving circuit GDC and the pixels PX₁₁ to PXₙₘ according to an embodiment may include a plurality of transistors formed through a low temperature polycrystalline silicon (LTPS) process, a low temperature polycrystalline oxide (LTPO) process, or an oxide semiconductor process.

The pads PD may be arranged in the non-display region NDA along one direction. The pads PD may be portions connected to a circuit board. Each of the pads PD may be connected to a corresponding signal line among the signal lines SL1 to SLn and DL1 to DLm and connected to a corresponding pixel among PX₁₁ to PXₙₘ through the signal line. The pads PD may have an integrated shape with the signal lines SL1 to SLn and DL1 to DLm. However, an embodiment of the inventive concept is not limited thereto, and the pads PD and the signal lines SL1 to SLn and DL1 to DLm may be disposed on different layers and connected to each other through a contact hole.

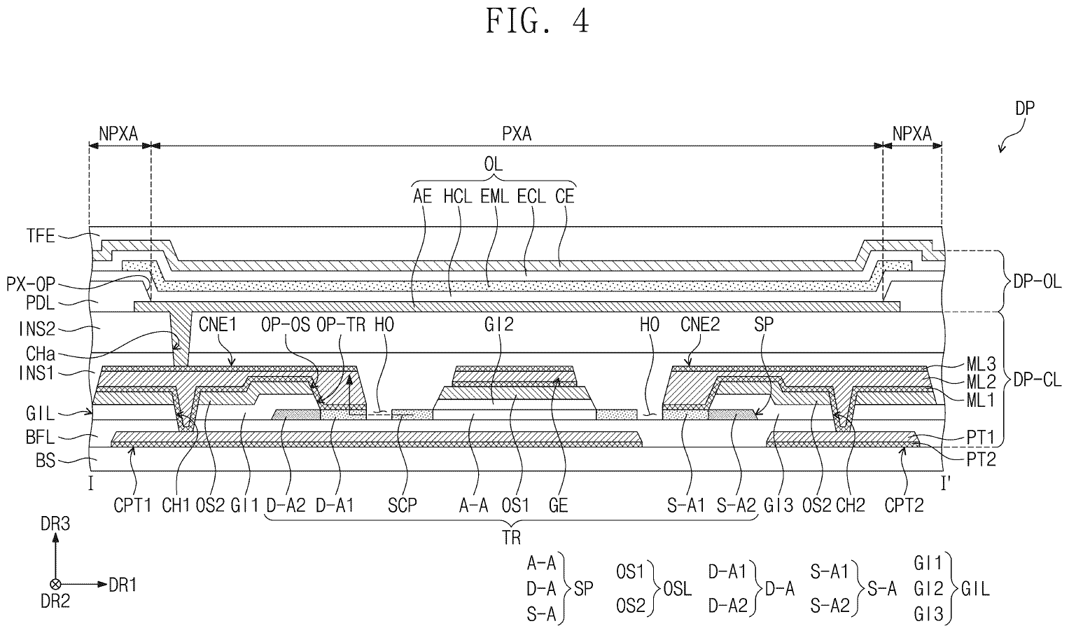

FIG. 4 is a cross-sectional view taken along line I-I′ of FIG. 3 according to an embodiment of the inventive concept.

Referring to FIG. 4, the display panel DP may include a base substrate BS, a circuit layer DP-CL, a display element layer DP-OL, and an encapsulation layer TFE.

The circuit layer DP-CL may include conductive patterns CPT1 and CPT2 disposed on the base substrate BS, a transistor TR, connection electrodes CNE1 and CNE2, a buffer layer BFL, a gate insulating pattern layer GIL, and insulating layers INS1 and INS2.

A first conductive pattern CPT1 and a second conductive pattern CPT2 may be disposed between the base substrate BS and the transistor TR and disposed to be spaced apart from each other in a plan view. The first conductive pattern CPT1 may be electrically connected to a first drain portion D-Al of a drain region D-A through a first connection electrode CNE1. The second conductive pattern CPT2 may be electrically connected to a first source portion S-A1 of a source region S-A through a second connection electrode CNE2.

Each of the first conductive pattern CPT1 and the second conductive pattern CPT2 may have a multi-layered structure. The first conductive pattern CPT1 and the second conductive pattern CPT2 may be formed of the same material and have the same stacked structure. For example, each of the first conductive pattern CPT1 and the second conductive pattern CPT2 may include a first pattern layer PT1 and a second pattern layer PT2 stacked on the base substrate BS in a thickness direction. However, an embodiment of the inventive concept is not necessarily limited thereto, and each of the first and second conductive patterns CPT1 and CPT2 may be provided as a single-layered structure or may also have a multi-layered structure in which more pattern layers than what is illustrated are stacked.

A thickness of the first pattern layer PT1 and a thickness of the second pattern layer PT2 may be different. For example, the thickness of the second pattern layer PT2 may be smaller than the thickness of the first pattern layer PT1. However, an embodiment of the inventive concept is not limited thereto.

Each of the first pattern layer PT1 and the second pattern layer PT2 may include molybdenum (Mo), aluminum (Al), chromium (Cr), gold (Au), titanium (Ti), nickel (Ni), neodymium (Nd), or copper (Cu), or an alloy thereof. For example, the first pattern layer PT1 may include titanium (Ti), and the second pattern layer PT2 may include copper (Cu). However, an embodiment of the inventive concept is not limited thereto.

The buffer layer BFL may be disposed on the base substrate BS to cover the first and second conductive patterns CPT1 and CPT2. The buffer layer BFL may include at least one inorganic film.

The transistor TR may include a semiconductor pattern SP, a first oxygen supply pattern OS1, and a gate electrode GE. The semiconductor pattern SP may be disposed on the buffer layer BFL. By the buffer layer BFL, a bonding force between the semiconductor pattern SP and the base substrate BS may be improved. The semiconductor pattern SP may include a semiconductor material such as polysilicon, crystalline silicon, or a metal oxide.

The source region S-A, an active region A-A, and the drain region D-A of the transistor TR may be formed from the semiconductor pattern SP. An electrical property of the semiconductor pattern SP may be changed according to whether the semiconductor pattern is doped or not or whether a metal oxide is reduced or not. The source region S-A and the drain region D-A of the semiconductor pattern SP having relatively high conductivity may serve as an electrode or a signal line. A region of the semiconductor pattern SP which is not doped or is doped with a low concentration, or in which a metal oxide is not reduced may correspond to the active region A-A having low conductivity. The active region A-A may be disposed between the source region S-A and the drain region D-A in a plan view.

The drain region D-A may include the first drain portion D-A1 and a second drain portion D-A2. The first drain portion D-A1 may be a portion having higher conductivity than the second drain portion D-A2. The first drain portion D-A1 may be a portion having first conductivity. The second drain portion D-A2 may have second conductivity which is lower than the first conductivity. The first drain portion D-A1 may be a region doped with a higher concentration than the second drain portion D-A2. Accordingly, when current flows in from the active region A-A, the current may flow in mostly through the first drain portion D-A1.

The source region S-A may include the first source portion S-A1 and a second source portion S-A2. The first source portion S-A1 may be a portion having high conductivity than the second source portion S-A2. The first source portion S-A1 may be a portion having third conductivity. The second source portion S-A2 may have fourth conductivity which is lower than the third conductivity. The first source portion S-A1 may be a region doped with a higher concentration than the second source portion S-A2. Accordingly, when current flows in the active region A-A, the current may flow in mostly through the first source portion S-A1.

At least one hole HO may be defined in the semiconductor pattern SP. At least one hole HO may be defined in the source region S-A or the drain region D-A. At least one hole HO may be disposed to be adjacent to either the source region S-A or the drain region D-A. The hole HO may be formed during an etching process of forming the connection electrodes CNE1 and CNE2 and the gate electrode GE. FIG. 4 exemplarily illustrates that holes HO spaced apart from each other are formed in the semiconductor pattern SP. One hole HO among the holes HO may be surrounded by the source region S-A in a plan view, and another hole HO may be surrounded by the drain region D-A. One hole HO among the holes HO may be surrounded by the first drain portion D-A1 in a plan view. Another hole HO among the holes HO may be surrounded by the first source portion S-A1. However, an embodiment of the inventive concept is not limited thereto, and according to a process for the circuit layer DP-CL, the hole HO may not be formed in the semiconductor pattern SP.

The gate insulating pattern layer GIL may be disposed on the buffer layer BFL. The gate insulating pattern layer GIL may include at least one inorganic film. The gate insulating pattern layer GIL may include first to third insulating patterns GI1, GI2, and GI3 which are spaced apart from each other. A first opening OP-TR may be defined in the gate insulating pattern layer GIL. A first gate insulating pattern GI1, a second gate insulating pattern GI2, and a third gate insulating pattern GI3 may be separated from each other by the first opening OP-TR in a cross-sectional view. The first gate insulating pattern GI1, the second gate insulating pattern GI2, and the third gate insulating pattern GI3 are shown as being separated from each other but may be substantially one component.

The first gate insulating pattern GI1 may cover the second drain portion D-A2 of the drain region D-A and may be disposed on the first conductive pattern CPT1. The second gate insulating pattern GI2 may be dispose on the active region A-A. The second gate insulating pattern GI2 may have a shape corresponding to that of the active region A-A. The second gate insulating pattern GI2 may cover the active region A-A. The third gate insulating pattern GI3 may cover the second source portion S-A2 of the source region S-A.

An oxygen supply pattern layer OSL may be disposed on the gate insulating pattern layer GIL. The oxygen supply pattern layer OSL may include a metal oxide. However, a material of the oxygen supply pattern layer OSL is not limited thereto, and may be any material capable of supplying oxygen to the active region A-A. The oxygen supply pattern layer OSL may include first and second oxygen supply patterns OS1 and OS2 spaced apart from each other. A pattern opening OP-OS may be defined in the oxygen supply pattern layer OSL. By the pattern opening OP-OS, the first oxygen supply pattern OS1 and the second oxygen supply pattern OS2 (or an additional insulating layer) may be separated.

The first oxygen supply pattern OS1 may be disposed between the gate insulating pattern layer GIL and the gate electrode GE. The first oxygen supply pattern OS1 may be disposed on the second gate insulating pattern GI2. The first oxygen supply pattern OS1 may be disposed between the second gate insulating pattern GI2 and the gate electrode GE. The first oxygen supply pattern OS1 may be directly disposed on the second gate insulating pattern GI2. The first oxygen supply pattern OS1 may be directly disposed on a lower surface of the gate electrode GE.

The first oxygen supply pattern OS1 may overlap the active region A-A. The first oxygen supply pattern OS1 may supply oxygen to the active region A-A. Oxygen supplied from the first oxygen supply pattern OS1 may be transferred to the active region A-A via the second gate insulating pattern GI2. The transferred oxygen may prevent conductivity of the active region A-A from excessively increasing due to decrease in length of the active region A-A in a first direction DR1, thereby improving reliability of a display device.

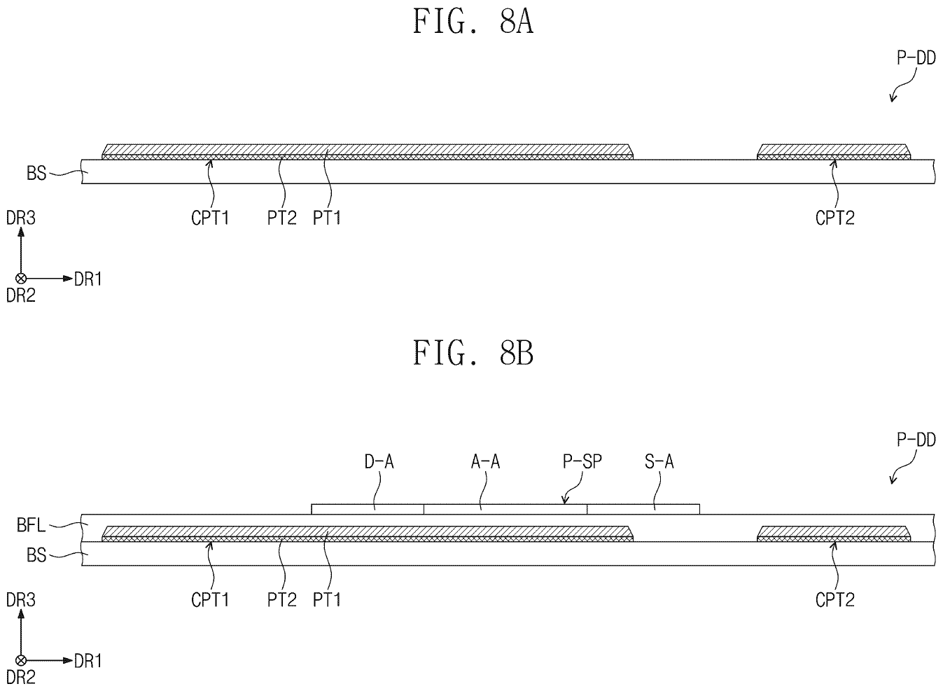

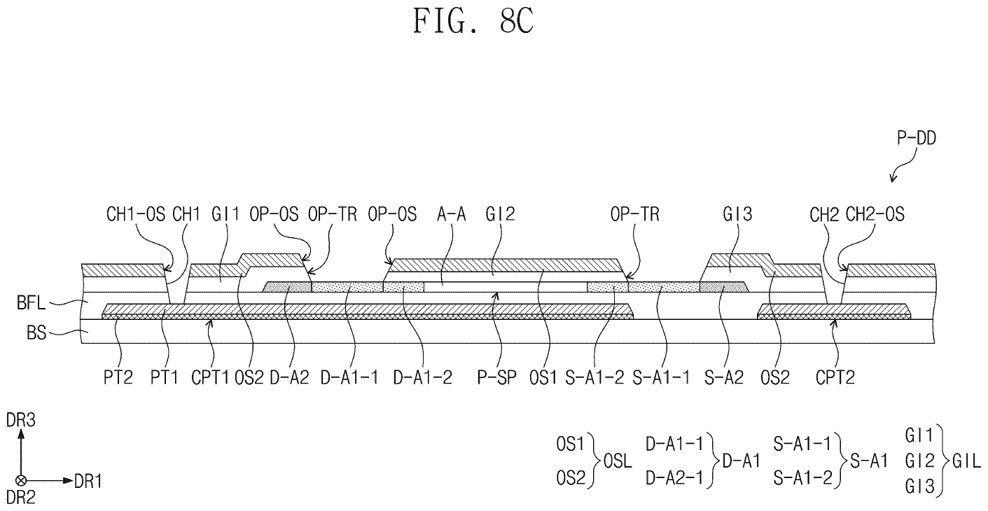

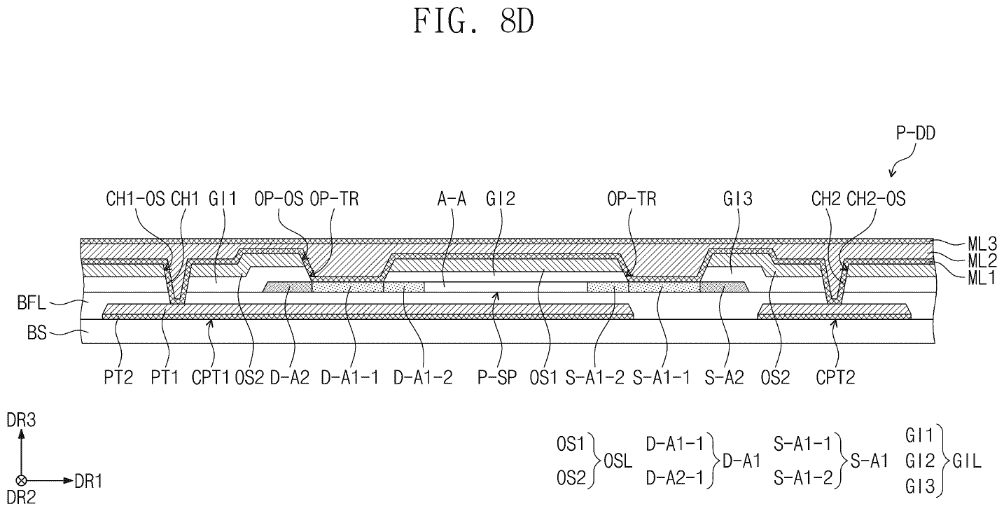

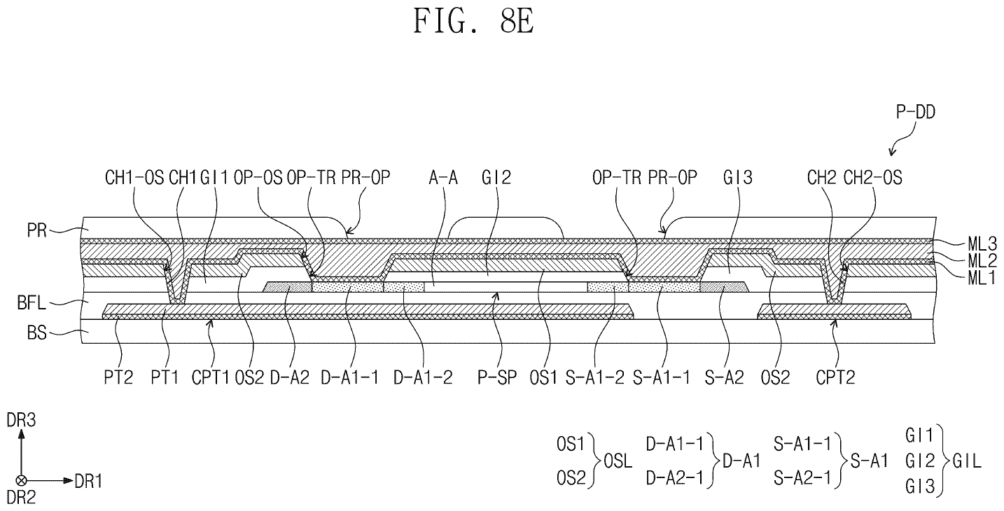

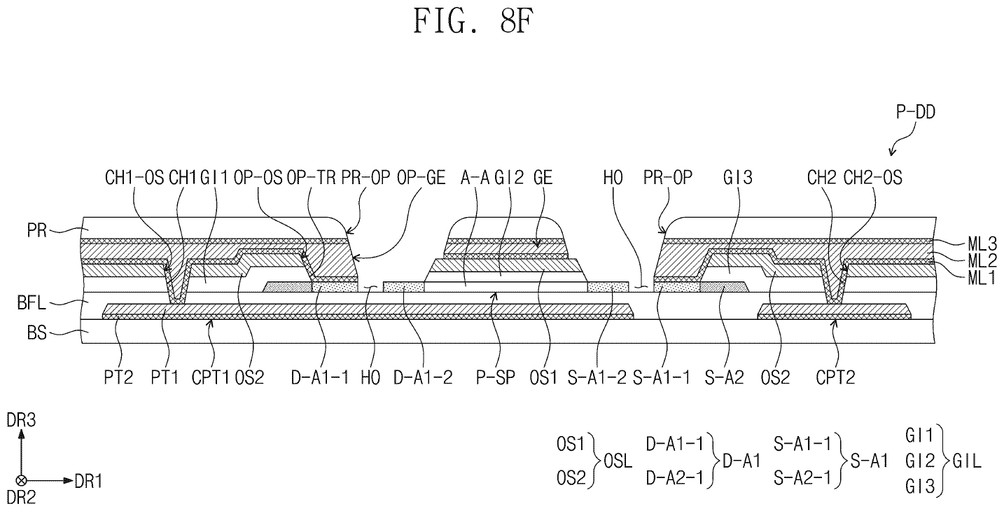

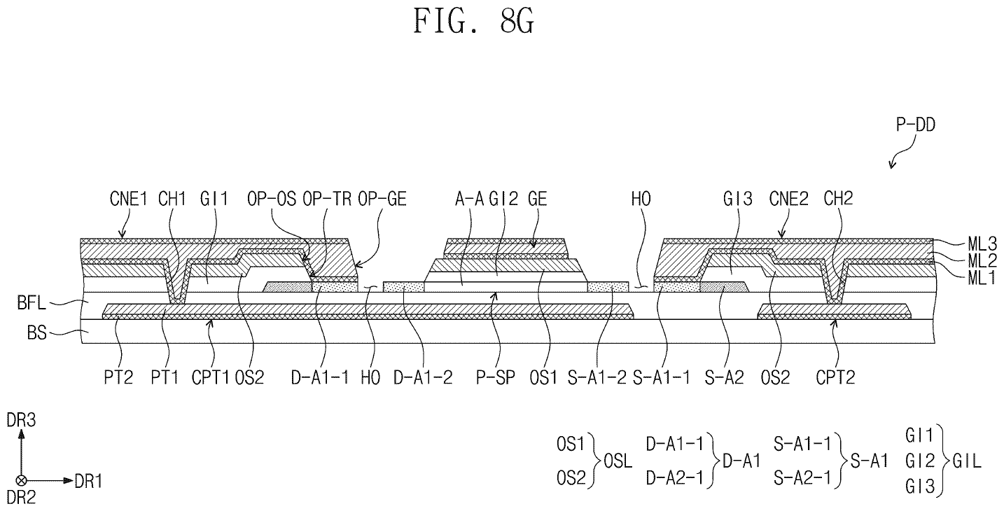

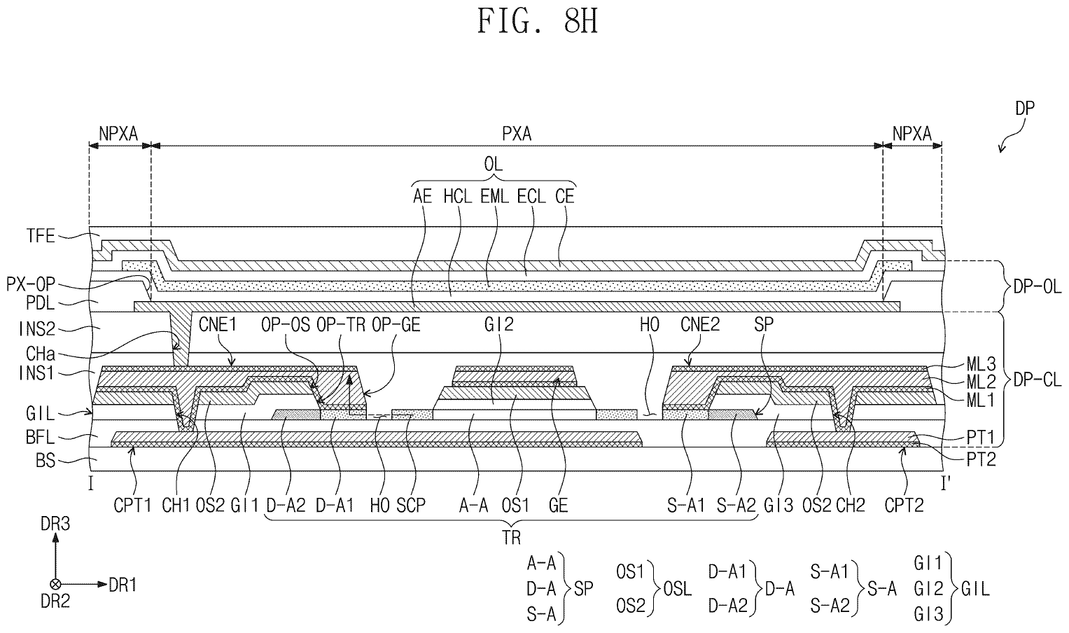

A shape of the first oxygen supply pattern OS1 may correspond to a shape of the second gate insulating pattern GI2. This is because the first oxygen supply pattern OS1 and the second gate insulating pattern GI2 are formed in the same etching process. Description thereof will be made later with reference to FIGS. 8A to 8H.

The second oxygen supply pattern OS2 (or an additional insulating layer) and the first oxygen supply pattern OS1 may be disposed on the same layer and include the same material. The second oxygen supply pattern OS2 may be directly disposed on lower surfaces of the connection electrodes CNE1 and CNE2 to be described later. Unlike the first oxygen supply pattern OS1, the second oxygen supply pattern OS2 may not overlap the active region A-A. The second oxygen supply pattern OS2 may include a material having greater electrical resistance than the connection electrodes CNE1 and CNE2. The second oxygen supply pattern OS2 may be disposed on the second drain portion D-A2 or the second source portion S-A2. The second oxygen supply pattern OS2 may cover the second drain portion D-A2 or the second source portion S-A2. The second oxygen supply pattern OS2 may not overlap the first drain portion D-A1 or the first source portion S-A1.

The second oxygen supply pattern OS2 may be disposed between the first connection electrode CNE1 and the gate insulating pattern layer GIL. The second oxygen supply pattern OS2 may be disposed between the second connection electrode CNE2 and the gate insulating pattern layer GIL.

The connection electrodes CNE1 and CNE2 may include the first connection electrode CNE1 and the second connection electrode CNE2. The first connection electrode CNE1 may be disposed on the first gate insulating pattern GI1. The first connection electrode CNE1 may be disposed on the second oxygen supply pattern OS2. The first connection electrode CNE1 may be connected to the first conductive pattern CPT1 through a first contact hole CH1 passing through the buffer layer BFL, the second oxygen supply pattern OS2, and the first gate insulating pattern GI1. The first connection electrode CNE1 may be in contact with the first drain portion D-A1 of the drain region D-A and electrically connected to the drain region D-A. The first drain portion D-A1 and the first conductive pattern CPT1 may be electrically connected to each other through the first connection electrode CNE1. Since the first conductive pattern CPT1 and the first drain portion D-A1 having excellent conductivity may be connected to the drain region D-A, a current transmitting property may be improved.

The first connection electrode CNE1 may be directly in contact with the drain region D-A. The first connection electrode CNE1 may be directly disposed on an upper surface of the first drain portion D-A1. The second oxygen supply pattern OS2 may be cut off by the pattern opening OP-OS before a contact point of the first connection electrode CNE1 and the first drain portion D-A1. Accordingly, the first oxygen supply pattern OS1 may be disposed between the active region A-A and the gate electrode GE, and the second oxygen supply pattern OS2 may not be disposed between the first drain portion D-A1 and the first connection electrode CNE1.

Since the first connection electrode CNE1 may be directly connected to the first drain portion D-A1, resistance may be reduced when an adjacent current flow SCP moves in a third direction DR3. That is, if the second oxygen supply pattern OS2 including a material having greater resistance than the first connection electrode CNE1 is disposed between the first drain portion D-A1 and the first connection electrode CNE1, resistance may be great when the adjacent current flow SCP moves toward the first connection electrode CNE1 along the third direction DR3. Such an increase in resistance may be prevented by directly connecting the first connection electrode CNE1 and the first drain portion D-A1.

The second connection electrode CNE2 may be disposed on the third gate insulating pattern GI3. The second connection electrode CNE2 may be disposed on the second oxygen supply pattern OS2. The second connection electrode CNE2 may be connected to the second conductive pattern CPT2 through a second contact hole CH2 passing through the buffer layer BFL, the second oxygen supply pattern OS2, and the third gate insulating pattern GI3. The second connection electrode CNE2 may be in contact with the first source portion S-A1 of the source region S-A and electrically connected to the source region S-A. The source region S-A and the second conductive pattern CPT2 may be electrically connected to each other through the second connection electrode CNE2. The second connection electrode CNE2 may be connected to a power line which supplies power to a light-emitting element OL and provide a first voltage to the transistor TR.

The second connection electrode CNE2 may be directly in contact with the source region S-A. The second connection electrode CNE2 may be directly disposed on an upper surface of the first source portion S-A1. The second oxygen supply pattern OS2 may be cut off by the pattern opening OP-OS before a contact point of the second connection electrode CNE2 and the first source portion S-A1. Accordingly, the second oxygen supply pattern OS2 may not be disposed between the first source portion S-A1 and the second connection electrode CNE2.

Since the second connection electrode CNE2 may be directly connected to the first source portion S-A1, resistance may be reduced when the adjacent current flow SCP moves in the third direction DR3. That is, if the second oxygen supply pattern OS2 including a material having greater resistance than the second connection electrode CNE2 is disposed between the first source portion S-A1 and the second connection electrode CNE2, resistance may be great when the adjacent current flow SCP moves toward the second connection electrode CNE2 along the third direction DR3. Such an increase in resistance may be prevented by directly connecting the second connection electrode CNE2 and the first source portion S-A1.

The gate electrode GE may be disposed on the second gate insulating pattern GI2. The gate electrode GE may overlap the active region A-A in a plan view, and may be spaced apart from the semiconductor pattern SP with the second gate insulating pattern GI2 and the first oxygen supply pattern OS1 therebetween in a thickness direction.

The connection electrodes CNE1 and CNE2 and the gate electrode GE may be spaced apart from each other in a plan view. The connection electrodes CNE1 and CNE2 and the gate electrode GE may be disposed on the same layer and include the same material. Each of the connection electrodes CNE1 and CNE2 and the gate electrode GE may have a multi-layered structure in which conductive layers ML1, ML2, and ML3 including different materials are stacked. The conductive layers ML1, ML2, and ML3 may include first to third conductive layers ML1, ML2, and ML3. The first to third conductive layers ML1, ML2, and ML3 may be stacked through a sputtering process, but an embodiment of the inventive concept is not limited thereto.

Each of the first to third conductive layers ML1, ML2, and ML3 may include a metal material. For example, each of the first to third conductive layers ML1, ML2, and ML3 may include molybdenum (Mo), aluminum (Al), chromium (Cr), gold (Au), titanium (Ti), nickel (Ni), neodymium (Nd), copper (Cu), or indium tin oxide (ITO), or alloy thereof. The first to third conductive layers ML1, ML2, and ML3 may include different metal materials. The second conductive layer ML2 may include a metal material having excellent conductivity, and the first and third conductive layers ML1 and ML3 respectively disposed under and on the second conductive layer ML2 may include a metal material having corrosion resistance. For example, the first conductive layer ML1 may include titanium (Ti), the second conductive layer ML2 may include copper (Cu), and the third conductive layer ML3 may include indium tin oxide (ITO). However, an embodiment of the inventive concept is not limited thereto.

Thicknesses of the first to third conductive layers ML1, ML2, and ML3 may be different from each other. For example, the second conductive layer ML2 including a material having high conductivity may have the greatest thickness among the first to third conductive layers ML1, ML2, and ML3. Thus, the connection electrodes CNE1 and CNE2 and the gate electrode GE which are formed from the first to third conductive layers ML1, ML2, and ML3 may have a property of low resistance and high conductivity.

FIG. 4 exemplarily illustrates that the connection electrodes CNE1 and CNE2 and the gate electrode GE have a multi-layered structure of three layers, but an embodiment of the inventive concept is not limited thereto, and the connection electrodes CNE1 and CNE2 and the gate electrode GE may have a multi-layered structure of more or fewer layers or may have a single-layered structure.

The connection electrodes CNE1 and CNE2 and the gate electrode GE may be simultaneously formed through the same process. The connection electrodes CNE1 and CNE2 and the gate electrode GE may have the same stacked structure. For example, the connection electrodes CNE1 and CNE2 and the gate electrode GE may have a three-layered structure of Ti/Cu/ITO. Since the connection electrodes CNE1 and CNE2 and the gate electrode GE may be simultaneously formed through the same process, the display panel DP may be manufactured through a simplified process.

A first insulating layer INS1 may be disposed on the gate insulating pattern layer GIL to cover the connection electrodes CNE1 and CNE2 and the gate electrode GE. A second insulating layer INS2 (or an insulating layer) may be disposed on the first insulating layer INS1. Each of the first insulating layer INS1 and the second insulating layer INS2 may include at least one inorganic film or organic film. The inorganic film may include at least one of aluminum oxide, titanium oxide, silicon oxide, silicon nitride, silicon oxynitride, zirconium oxide, or hafnium oxide, but is not limited to the material. The organic film may include a phenol-based polymer, an acrylic polymer, an imide-based polymer, an arylether-based polymer, an amide-based polymer, a fluorine-based polymer, a p-xylene-based polymer, a vinyl alcohol-based polymer, and a combination thereof, but is not limited to the material.

The display element layer DP-OL may be disposed on the circuit layer DP-CL. The display element layer DP-OL may include a pixel-defining film PDL and the light-emitting element OL. As an example, the light-emitting element OL may include an organic light-emitting element, an inorganic light-emitting element, a quantum dot light-emitting element, a micro-LED light-emitting element, or a nano-LED light-emitting element. An embodiment of the inventive concept is not limited thereto, and the light-emitting element OL may include various embodiments as long as light may be generated or the amount of light may be controlled in response to an electrical signal.

The pixel-defining film PDL may be disposed on the second insulating layer INS2 of the circuit layer DP-CL. The pixel-defining film PDL may include a polymer resin. For example, the pixel-defining film PDL may include a polyacrylate-based resin or a polyimide-based resin. The pixel-defining film PDL may further include an inorganic material in addition to a polymer resin. In addition, the pixel-defining film PDL may be formed of an inorganic material. For example, the pixel-defining film PDL may include silicon nitride (SiNₓ), silicon oxide (SiOₓ), silicon oxynitride (SiOₓN_{y}), or the like.

In an embodiment, the pixel-defining film PDL may include a light absorbing material. The pixel-defining film PDL may include a black coloring agent. The black coloring agent may include black dye or a black pigment. The black coloring agent may include carbon black, metal such as chromium, or an oxide thereof. However, an embodiment of the pixel-defining film PDL is not limited to the example.

The light-emitting element OL may include a first electrode AE, a hole transport region HCL, an emission layer EML, an electron transport region ECL, and a second electrode CE, which are sequentially stacked.

The first electrode AE may be disposed on the second insulating layer INS2 of the circuit layer DP-CL. The first electrode AE may be connected to the first connection electrode CNE1 through a contact hole CHa passing through the first insulating layer INS1 and the second insulating layer INS2. The first connection electrode CNE1 may electrically connect the first electrode AE and the transistor TR. That is, the first electrode AE may be connected to the first connection electrode CNE1, and the drain region D-A may thus be connected to the light-emitting element OL through the first connection electrode CNE1.

A light-emitting opening PX-OP extending to at least a portion of the first electrode AE may be defined in the pixel-defining film PDL. A portion of the first electrode AE to which the light-emitting opening PX-OP extends may correspond to a light-emitting region PXA. A region in which the pixel-defining film PDL is disposed may correspond to a non-light-emitting region NPXA. The non-light-emitting region NPXA may surround the light-emitting region PXA.

The hole transport region HCL may be disposed on the first electrode AE. The hole transport region HCL may include at least one of a hole injection layer, a hole transport layer, or an electron blocking layer. In addition, the hole transport region HCL may include a plurality of hole transport layers.

The emission layer EML may be disposed on the hole transport region HCL. The emission layer EML may have a single-layered structure formed of a single material, a single-layered structure formed of different materials, or a multi-layered structure having a plurality of layers formed of a plurality of different materials. In an embodiment, the emission layer EML may generate blue light which becomes source light. However, an embodiment of the inventive concept is not limited thereto, and the display element layer DP-OL may include light-emitting elements OL each having an emission layer EML which emits light of a different wavelength range.

The emission layer EML may be provided in a form of a pattern disposed in a region corresponding to the light-emitting opening PX-OP. However, an embodiment of the inventive concept is not limited thereto, and the emission layer EML may be provided as a common layer overlapping the light-emitting region PXA and the non-light-emitting region NPXA.

The electron transport region ECL may be disposed on the emission layer EML. The electron transport region ECL may include at least one of a hole blocking layer, an electron transport layer, or an electron injection layer, but an embodiment of the inventive concept is not limited thereto.

Each of the hole transport region HCL, the emission layer EML, and the electron transport region ECL may be formed by using various methods such as a vacuum deposition method, a spin coating method, a casting method, a Langmuir-Blodgett (LB) method, an inkjet printing method, a laser printing method, and a laser induced thermal imaging (LITI) method.

The second electrode CE may be disposed on the electron transport region ECL. The second electrode CE may be a common electrode. That is, the second electrode CE of an embodiment may be provided as a common layer so as to overlap with all of the light-emitting region PXA and the non-light-emitting region NPXA.

The encapsulation layer TFE may cover the light-emitting element OL. The encapsulation layer TFE may encapsulate the display element layer DP-OL. The encapsulation layer TFE may include at least one insulating film. The encapsulation layer TFE according to an embodiment may include at least one inorganic film (hereinafter, an inorganic encapsulation film). The encapsulation layer TFE according to an embodiment may include inorganic encapsulation films and at least one organic film (hereinafter, an organic encapsulation film) disposed between the inorganic encapsulation films.

The inorganic encapsulation film may protect the display element layer DP-OL from moisture/oxygen, and the organic encapsulation film may protect the display element layer DP-OL from foreign substances such as dust particles. The inorganic encapsulation film may include silicon nitride, silicon oxynitride, silicon oxide, titanium oxide, aluminum oxide, or the like, and is not particularly limited thereto. The organic encapsulation film may include an acrylic compound, an epoxy-based compound, etc. The organic encapsulation film may include a photopolymerizable organic material and is not particularly limited.

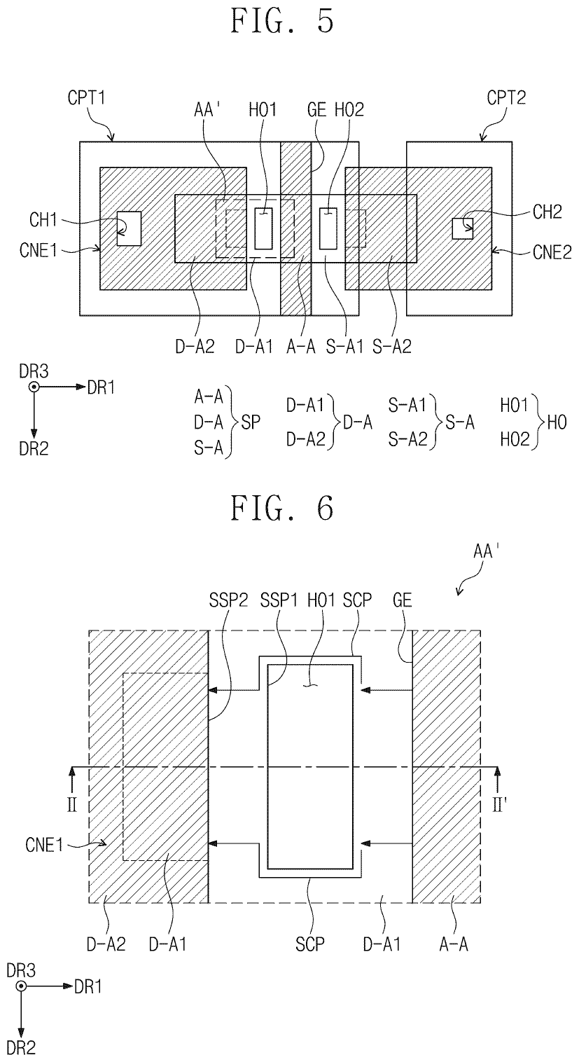

FIG. 5 is a plan view corresponding to the circuit layer of FIG. 4 according to an embodiment of the inventive concept. Specifically, FIG. 5 illustrates a plan view of the first conductive pattern CPT1, the second conductive pattern CPT2, the semiconductor pattern SP, the gate electrode GE, the first connection electrode CNE1, and the second connection electrode CNE2.

Referring to FIG. 5, the first conductive pattern CPT1 and the second conductive pattern CPT2 may be disposed to be spaced apart from each other in a plan view. The first connection electrode CNE1 and the second connection electrode CNE2 may be disposed to be spaced apart from each other in a plan view. The first connection electrode CNE1 and the second connection electrode CNE2 may be disposed on the gate insulating pattern layer GIL (see FIG. 4). The first connection electrode CNE1 may be electrically connected to the first conductive pattern CPT1 through the first contact hole CH1. The second connection electrode CNE2 may be electrically connected to the second conductive pattern CPT2 through the second contact hole CH2.

The semiconductor pattern SP may overlap the first connection electrode CNE1, the second connection electrode CNE2, and the gate electrode GE. The semiconductor pattern SP may overlap the first conductive pattern CPT1 and the second conductive pattern CPT2. However, an embodiment of the inventive concept is not limited thereto, and the semiconductor pattern SP may have various shapes. For example, the semiconductor pattern SP may not overlap with the second conductive pattern CPT2.

The semiconductor pattern SP may include a semiconductor material such as polysilicon, crystalline silicon, or a metal oxide. The semiconductor pattern SP may include the active region A-A, the source region S-A, and the drain region D-A. An electrical property of the semiconductor pattern SP may be changed according to whether the semiconductor pattern is doped or not or whether a metal oxide is reduced or not. The source region S-A and the drain region D-A of the semiconductor pattern SP having relatively high conductivity may serve as an electrode or a signal line. A region of the semiconductor pattern SP which is not doped or is doped with a low concentration, or in which a metal oxide is not reduced may correspond to the active region A-A having low conductivity. The active region A-A of the semiconductor pattern SP may be a portion of the semiconductor pattern SP overlapping the gate electrode GE. The active region A-A may have low conductivity than the source region S-A and the drain region D-A.

At least one hole HO may be defined in the semiconductor pattern SP of the transistor TR (see FIG. 4). The hole HO may be disposed to be adjacent to either the source region S-A or the drain region D-A. The hole HO may be formed during an etching process of forming the first connection electrode CNE1, the second connection electrode CNE2, and the gate electrode GE. The hole HO may be defined in plurality. FIG. 5 exemplarily illustrates that the holes HO spaced apart from each other are formed.

The holes HO may include a first hole HO1 and a second hole HO2. The first hole HO1 may be surrounded by the drain region D-A. The first hole HO1 may be surrounded by the first drain portion D-A1. The first hole HO1 may not overlap with the second drain portion D-A2. The second hole HO2 may be surrounded by the first source portion S-A1. The second hole HO2 may not overlap with the second source portion S-A2.

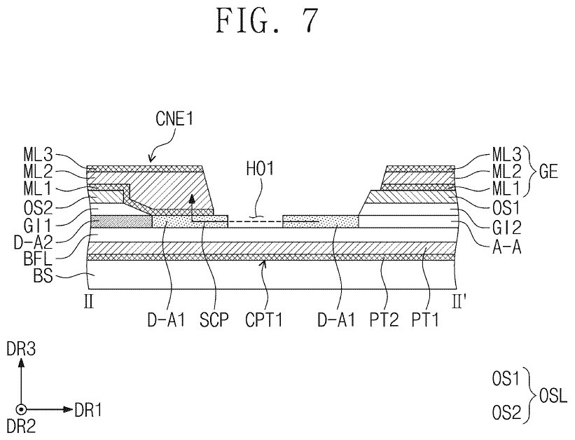

FIG. 6 is an enlarged plan view of a region AA′ of FIG. 5 according to an embodiment of the inventive concept.

Hereinafter, the same component as the component described above will be denoted as the same reference numerals or symbols, and detailed description thereof will be omitted. In addition, description of the drain region D-A and the first hole HO1 with reference to FIG. 6 may be equally applied to the source region S-A (see FIG. 5) and the second hole HO2 (see FIG. 5).

Referring to FIG. 6, current from the active region A-A may avoid the first hole HO1 and may be introduced into the first drain portion D-A1. Since current is not allowed to flow in the first hole HO1, an adjacent current flow SCP may avoid the first hole HO1 and may be introduced into the first drain portion D-A1. The first hole HO1 may be disposed to be spaced apart from the first drain portion D-A1 by a predetermined distance. The adjacent current flow may move along a second direction DR2 or a direction opposed to the second direction DR2 through a gap having the predetermined distance, and then may move in a direction opposed to a first direction DR1 and may be introduced into the first drain portion D-A1. To this end, an inner side surface SSP1 of the semiconductor pattern SP (see FIG. 5) defining the first hole HO1 and one side surface SSP2 of the first connection electrode CNE1 adjacent thereto may be disposed to be spaced apart from each other in the first direction DR1.

FIG. 7 is a cross-sectional view taken along line II-II′ of FIG. 6 according to an embodiment of the inventive concept. Hereinafter, the same component as the component described above will be denoted as the same reference numerals or symbols, and detailed description thereof will be omitted.

Referring to FIG. 7, the first gate insulating pattern GI1 may cover the second drain portion D-A2. The first drain portion D-A1 may be directly in contact with and electrically connected to the first connection electrode CNE1. The adjacent current flow SCP from the active region A-A may avoid the first hole HO1 and travel in a direction opposed to a first direction DR1 through the first drain portion D-A1. The adjacent current flow SCP may move in a third direction DR3 at a contact portion of the first drain portion D-A1 and the first connection electrode CNE1 and may be introduced into the first connection electrode CNE1.

The first oxygen supply pattern OS1 may overlap the active region A-A and allow oxygen to be supplied to the active region A-A, and the second oxygen supply pattern OS2 may not be disposed between the first connection electrode CNE1 and the first drain portion D-A1 so as not to interrupt the adjacent current flow SCP. That is, reliability of the transistor TR (see FIG. 4) may be improved through the first oxygen supply pattern OS1, and an increase in resistance of an element due to disposition of the second oxygen supply pattern OS2 in a path of the adjacent current flow SCP may be prevented.

FIGS. 8A to 8H are cross-sectional views partially showing a manufacturing method of a display device according to an embodiment of the inventive concept. Hereinafter, the same component as the component described above will be denoted as the same reference numerals or symbols, and detailed description thereof will be omitted.

Referring to FIG. 8A, a preliminary display device P-DD including a base substrate BS, a first conductive pattern CPT1 disposed on the base substrate BS, and a second conductive pattern CPT2 spaced apart from the first conductive pattern CPT1 in a plan view may be prepared. Each of the first conductive pattern CPT1 and the second conductive pattern CPT2 may include a first pattern layer PT1 and a second pattern layer PT2 stacked in a thickness direction.

Referring to FIG. 8B, a buffer layer BFL which covers the first conductive pattern CPT1 and the second conductive pattern CPT2 may be formed. On the buffer layer BFL, a preliminary semiconductor pattern P-SP including a source region S-A, an active region A-A, and a drain region D-A may be formed.

Referring to FIG. 8C, a gate insulating pattern layer GIL may be formed on the preliminary semiconductor pattern P-SP. An oxygen supply pattern layer OSL may be formed on the gate insulating pattern layer GIL. A first contact hole CH1 exposing an upper surface of the first conductive pattern CPT1 may be formed in the gate insulating pattern layer GIL. A second contact hole CH2 exposing an upper surface of the second conductive pattern CPT2 may be formed in the gate insulating pattern layer GIL. A first opening OP-TR exposing a first portion of the preliminary semiconductor pattern P-SP may be formed in the gate insulating pattern layer GIL. The gate insulating pattern layer GIL may include first to third insulating patterns GI1, GI2, and GI3 spaced apart from each other. A first gate insulating pattern GI1 may cover a second drain portion D-A2. A second gate insulating pattern GI2 may cover a first-second drain portion D-A1-2, the active portion A-A, and a first-second source portion S-A1-2. A third gate insulating pattern GI3 may cover a second source portion S-A2.

A first pattern contact hole CH1-OS exposing the upper surface of the first conductive pattern CPT1 may be formed in the oxygen supply pattern layer OSL. The first pattern contact hole CH1-OS and the first contact hole CH1 may be simultaneously formed. A second pattern contact hole CH2-OS exposing the upper surface of the second conductive pattern CPT2 may be formed in the oxygen supply pattern layer OSL. The second pattern contact hole CH2-OS and the second contact hole CH2 may be simultaneously formed.

A first opening OP-OS exposing the first portion of the preliminary semiconductor pattern P-SP may be formed in the oxygen supply pattern layer OSL. The oxygen supply pattern layer OSL may include a first oxygen supply pattern OS1 and a second oxygen supply pattern OS2 spaced apart from each other. The first oxygen supply pattern OS1 and the second oxygen supply pattern OS2 may be spaced apart from each other with the first opening OP-OS therebetween. That is, the first contact hole CH1, the second contact hole CH2, and the first opening OP-TR of the gate insulating pattern layer GIL and the first pattern contact hole CH1-OS, the second pattern contact hole CH2-OS, and the first opening OP-OS of the oxygen supply pattern layer OSL may be formed through the same etching process.

When forming the first openings OP-TR and OP-OS, the first portion of the preliminary semiconductor pattern P-SP exposed by the first openings OP-TR and OP-OS may be doped. Here, a first-first drain portion D-A1-1 and a first-first source portion S-A1-1 which are exposed may be doped.

Referring to FIG. 8D, conductive layers ML1, ML2, and ML3 may be formed on the oxygen supply pattern layer OSL. The conductive layers ML1, ML2, and ML3 may include first to third conductive layers ML1, ML2, and ML3. The conductive layers ML1, ML2, and ML3 may cover the preliminary semiconductor pattern P-SP. The conductive layers ML1, ML2, and ML3 may fill the first contact hole CH1, the second contact hole CH2, the first pattern contact hole CH1-OS, the second pattern contact hole CH2-OS, and the first openings OP-TR and OP-OS. Here, a first conductive layer ML1 may be directly in contact with the first-first drain portion D-A1-1 and the first-first source portion S-A1-1.

Referring to FIG. 8E, a photoresist layer PR having a photo opening PR-OP defined therein may be formed on the conductive layers ML1, ML2, and ML3. The photoresist layer PR may be formed so that a portion corresponding to the photo opening PR-OP is etched.

Referring to FIG. 8F, a second opening OP-GE corresponding to the photo opening PR-OP may be formed in the conductive layers ML1, ML2, and ML3. The second opening OP-GE may expose a portion of the first portion of the preliminary semiconductor pattern P-SP. That is, a portion of each of the first-first drain portion D-A1-1 and the first-first source portion S-A1-1 may be exposed. The conductive layers ML1, ML2, and ML3 may be divided into a gate electrode GE, a first connection electrode CNE1, and a second connection electrode CNE2 by the second opening OP-GE. The gate electrode GE may correspond to the active region A-A.

In addition, a portion of the second gate insulating pattern GI2 corresponding to the second opening OP-GE may be etched. Here, the first-second drain portion D-A1-2 and the first-second source portion S-A1-2 covered with the second gate insulating pattern GI2 may be doped.

In addition, a hole HO disposed to be adjacent to either the source region S-A or the drain region D-A may be formed in the preliminary semiconductor pattern P-SP. The hole HO may be provided in plurality, and each of the holes HO may overlap with a first drain portion D-A1 or overlap a first source portion S-A1. The hole HO may pass through a semiconductor pattern SP. A portion of an upper surface of the buffer layer BFL may be exposed to the outside by the hole HO.

Referring to FIG. 8G, the photoresist layer PR serving as an existing mask may be removed. An end of the first connection electrode CNE1 formed here may be in contact with the first-first drain portion D-A1-1, and an end of the second connection electrode CNE2 may be in contact with the first-first source portion S-A1-1.

Referring to FIG. 8H, a display panel DP may be formed by forming insulating layers INS1 and INS2, a display element layer DP-OL, and an encapsulation layer TFE on the preliminary display device P-DD of FIG. 8G. Description of a detailed configuration is made above and thus omitted.

A display device according to the inventive concept may include an oxygen supply pattern overlapping an active region and supply oxygen to the active region, thereby improving reliability of the active region.

In addition, a connection electrode may be directly in contact with a semiconductor pattern without the oxygen supply pattern therebetween, thereby reducing resistance of an element.

Although description has been made with reference to the embodiments of the inventive concept, it is understood that the inventive concept should not be limited to these embodiments, but various changes and modifications may be made by one ordinary skilled in the art within the spirit and scope of the inventive concept as hereinafter claimed. Therefore, the technical scope of the inventive concept is not limited to the contents described in the detailed description of the specification, but should be determined by the accompanying claims.

What is claimed is:

1. A display device comprising:
a base substrate;
a transistor disposed on the base substrate and including a semiconductor pattern including a source region, an active region and a drain region, and a gate electrode;
a gate insulating pattern layer disposed on the semiconductor pattern;
an oxygen supply pattern disposed between the gate insulating pattern layer and the gate electrode, overlapping the active region, and configured to supply oxygen to the active region; and
a connection electrode disposed on the gate insulating pattern layer and electrically connected to the semiconductor pattern,
wherein a first hole disposed to be adjacent to either the source region or the drain region is defined in the semiconductor pattern, and
the connection electrode is directly in contact with the semiconductor pattern.

2. The display device of claim 1, wherein the gate insulating pattern layer is disposed on the active region and comprises a gate insulating pattern having a shape corresponding to the active region, and a shape of the oxygen supply pattern corresponds to the gate insulating pattern.

3. The display device of claim 1, wherein the oxygen supply pattern overlaps the active region.

4. The display device of claim 1, wherein the connection electrode is provided in plurality, and
the plurality of the connection electrodes comprise:
a first connection electrode directly in contact with the drain region; and
a second connection electrode directly in contact with the source region.

5. The display device of claim 4, wherein the drain region comprises
a first drain portion having first conductivity, and
a second drain portion extending from the first drain portion and having second conductivity which is lower than the first conductivity, and
the source region comprises
a first source portion having third conductivity, and
a second source portion extending from the first source portion and having fourth conductivity which is lower than the third conductivity.

6. The display device of claim 5, wherein the first connection electrode is directly in contact with the first drain portion, and
the second connection electrode is directly in contact with the first source portion.

7. The display device of claim 5, wherein in a plan view, the first hole is surrounded by the first source portion, or is surrounded by the first drain portion.

8. The display device of claim 5, further comprising a first conductive pattern and a second conductive pattern disposed between the base substrate and the transistor and spaced apart from each other in a plan view,
wherein the first conductive pattern is electrically connected to the first drain portion through the first connection electrode, and
the second conductive pattern is electrically connected to the first source portion through the second connection electrode.

9. The display device of claim 1, further comprising an additional insulating layer disposed on a lower surface of the connection electrode and not overlapping with the active region,
wherein the additional insulating layer and the oxygen supply pattern are disposed on the same layer and include the same material.

10. The display device of claim 9, wherein the additional insulating layer comprises a material having greater electrical resistance than the connection electrode.

11. The display device of claim 1, wherein an inner side surface of the semiconductor pattern defining the first hole and one side surface of the connection electrode adjacent to the inner side surface are spaced apart from each other.

12. The display device of claim 1, further comprising a light-emitting element disposed on the connection electrode and including a first electrode connected to the connection electrode, an emission layer, and a second electrode,
wherein the connection electrode electrically connects the first electrode and the transistor.

13. The display device of claim 1, wherein the connection electrode and the gate electrode are disposed on the same layer and comprise the same material.

14. A display device comprising:
a base substrate;
a transistor disposed on the base substrate and including a semiconductor pattern including a source region, an active region and a drain region, and a gate electrode;
a gate insulating pattern layer disposed on the semiconductor pattern;
an oxygen supply pattern layer disposed on the gate insulating pattern layer; and
a connection electrode disposed on the gate insulating pattern layer and electrically connected to the semiconductor pattern,
wherein a first hole disposed to be adjacent to either the source region or the drain region is defined in the semiconductor pattern, and
the oxygen supply pattern layer includes
a first oxygen supply pattern disposed between the gate insulating pattern layer and the gate electrode, and
a second oxygen supply pattern directly disposed on a lower surface of the connection electrode and not overlapping the active region.

15. The display device of claim 14, wherein the connection electrode is directly in contact with the source region or the drain region.

16. A method of manufacturing a display device, the manufacturing method comprising:
preparing a preliminary display device including a base substrate, a preliminary semiconductor pattern including a source region, an active region, and a drain region disposed on the base substrate, and a gate insulating pattern layer disposed on the preliminary semiconductor pattern;
forming an oxygen supply pattern layer on the gate insulating pattern layer;
forming a first opening exposing a first portion of the preliminary semiconductor pattern in the gate insulating pattern layer and the oxygen supply pattern layer;
forming a conductive layer on the oxygen supply pattern layer;
forming a gate electrode and a connection electrode from the conductive layer by forming a second opening exposing a portion of the first portion of the preliminary semiconductor pattern in the conductive layer; and
forming a semiconductor pattern from the preliminary semiconductor pattern by forming a first hole disposed to be adjacent to either the source region or the drain region in the preliminary semiconductor pattern.

17. The method of claim 16, wherein the connection electrode is directly in contact with the source region or the drain region.

18. The method of claim 16, further comprising, after forming the first opening, doping the first portion of the preliminary semiconductor pattern exposed by the first opening.

19. The method of claim 16, wherein the forming of the gate electrode and the connection electrode comprises:
forming a photoresist layer having a photo opening defined therein on the conductive layer; and
etching the conductive layer.

20. The method of claim 16, wherein the drain region comprises:
a first drain portion having first conductivity, and
a second drain portion extending from the first drain portion and having second conductivity which is lower than the first conductivity,
the source region comprises
a first source portion having third conductivity, and
a second source portion extending from the first source portion and having fourth conductivity which is lower than the third conductivity,
the connection electrode is provided in plurality, and
the plurality of the connection electrodes comprise
a first connection electrode directly in contact with the first drain portion, and
a second connection electrode directly in contact with the first source portion.
